(19) United States
(12) Patent Application Publication
(10) Pub. No.: US 2012/0309118 A1
(43) Pub. Date: Dec. 6, 2012

(54) SILICON WAFER ALIGNMENT METHOD USED IN THROUGH-SILICON-VIA INTERCONNECTION

(75) Inventors: Pengfei Wang, Shanghai (CN); Qingqing Sun, Shanghai (CN); Shijin Ding, Shanghai (CN); Wei Zhang, Shanghai (CN)

(73) Assignee: Fudan University, Shanghai (CN)

(21) Appl. No.: 13/304,149

(22) Filed: Nov. 23, 2011

Related U.S. Application Data
(63) Continuation of application No. PCT/CN2011/000608, filed on Apr. 8, 2011.

(30) Foreign Application Priority Data
Apr. 8, 2010 (CN) 201010141746.6

(51) Int. Cl. H01L 21/66

(52) U.S. Cl. 438/15; 257/E21.531

(57) ABSTRACT

A method of silicon wafer alignment used in through-silicon-via interconnection for use in the field of high-integrity packaging technology is disclosed. In one aspect, the method includes aligning and calibrating the upper and lower silicon wafers, stacked and interconnected electrically, so as to improve alignment accuracy of silicon wafers and reduce interconnection resistances. In some embodiments, the integrated circuit chip made by the method improves speed and energy performance.

### FIELD OF INVENTION

The present invention belongs to the field of high-integrity packaging technology, and more specifically, relates to a packaging method of Through-Silicon-Via interconnections.

### BACKGROUND OF THE INVENTION

With the continuous development of microelectronic technology, the chip manufacturing process is becoming fine, thus promoting the continuous growth of integrated circuit packaging technology, and gradually forming a relatively independent technology industry. Nowadays, three-dimensional packaging technology has been considered as the future trend of the development of integrated circuit packaging technology. Moreover, three-dimensional packaging technology has grown from chip level stacked die packaging technology or Package on Package technology to the wafer level of Through-Silicon-Via interconnection packaging technology.

Through-Silicon-Via interconnection technology is working by making vertical through holes among silicon layers, and then interconnection microscale solder joints are formed in the front and the back. Therefore, several silicon wafers can be directly stacked rather than interconnected by means of external leads. Through-Silicon-Via interconnection technology can be divided into two kinds: first-through-holes type (via first) and last-through-holes type (via last). In the first-through-holes technology, the Through-Silicon-Via interconnection is made prior to the manufacturing of the integrated circuit in silicon. In this technology, the Through-Silicon-Via interconnection can be either formed in the primary steps of the chip manufacturing or before Back-end of Line (BEOL), while, in the last-through-holes technology, the Through-Silicon-Via interconnection is made after the manufacturing of the BEOL or of the whole integrated circuit. The materials filled in the Through-Silicon-Via include an insulating layer and a metal layer for conduction or high doped polycrystalline silicon. Considering the reduction of interconnection resistance and the improvement of the working frequency of the chips, it is favorable to use copper as the metal of the Through-Silicon-Via interconnection in the Through-Silicon-Via three-dimensional packaging of multi-sensor system. Different from the technology of the IC packaging and bonding as well as Package on Package technology by using bumps in the prior art, the Through-Silicon-Via interconnection technology can maximize the density of chips stacked in the three-dimensional direction, minimize the external sizes and greatly improve the performance of wafer speed and low energy consumption.

As the most advanced wafer level packaging technology, Through-Silicon-Via interconnection technology now is still in the early development stage. There are a lot of technical difficulties such as wafer thinning technology, silicon wafer alignment technology, deep hole etching technology and deep hole copper filling process and equipment that all require re-development. During stacking, the alignment of the silicon wafer may influence the interconnection resistance between silicon wafers, thus further affecting the working frequency of wafers, in this way to prevent the three-dimensional stacking of wafers from wider application in more fields.

### BRIEF SUMMARY OF THE INVENTION

The present invention aims at putting forward a method of silicon wafer alignment used in Through-Silicon-Via interconnection so as to reduce the interconnection resistance between the silicon wafers during stacking and improving the working frequency of wafers, thus realizing the application of the three-dimensional lamination of wafers in wider areas.

To achieve the abovementioned purpose, the present invention provides a method of assistant alignment to the upper and lower silicon wafers stacked and interconnected electrically, characterized in that, comprising the following steps specifically:

providing two or more silicon wafers with completed Through-Silicon-Via structure;

forming interconnected microscale solder joints on the front and the back faces of the silicon wafers;

stacking and interconnecting the silicon wafers;

aligning and calibrating the upper and lower silicon wafers stacked and interconnected electrically.

Furthermore, the Through-Silicon-Via structure at least includes a conductive layer and an insulating layer for separating the conductive layer from the Through-Silicon-Via surface, wherein the insulating layer is made of silicon dioxide, silicon nitride or the insulating substance of their combination, and the conductive layer is made of aluminum, copper or high doped polycrystalline silicon.

The electrical method refers to balanced Wheatstone bridge, specifically includes: when the solder joint at the bottom of the upper silicon wafer contacts with the solder joint on the top of the lower silicon wafer, 4 contact resistors are formed, wherein, every two resistor groups is connected in series to form a group, the electrical node between two electrical resistor groups is A, afterwards, make the two groups of resistor groups in series parallel-connected; apply a voltage on both ends of the two groups of resistor in parallel, compare the two nodes A (shown as b and d in FIG. 3b) in the two groups of resistor to get voltage difference, and the voltage difference of the two nodes A measured when the upper and lower silicon wafers are completely aligned with each other is 0V; the smaller the voltage difference between the two electrical nodes A is, the better the alignment of the upper and lower silicon wafers is.

The silicon wafer alignment method put forward by the present invention has the advantages of simple implementation method, improved alignment accuracy of silicon wafers and reduced interconnection resistances. The integrated circuit chip made by the technology of the present invention features the performance of high speed and low energy consumption.

### BRIEF DESCRIPTION OF THE SEVERAL VIEWS OF THE DRAWINGS

FIG. 1 shows two silicon wafers with completed Through-Silicon-Via structure and interconnected solder joints.

FIG. 2 is the schematic view of two silicon wafers in FIG. 1 after contacting with each other.

FIG. 3a to FIG. 3d are the schematic view of principles for calibrating and aligning the silicon wafers after contacting in FIG. 2 by means of balanced Wheatstone bridge according to the present invention.

### DETAILED DESCRIPTION OF THE INVENTION

The exemplary embodiments of the present invention will be illustrated hereinafter by reference to the drawings. The drawings are the schematic view of ideal embodiment for the present invention. The embodiments, without constituting the limitation to the present invention, are illustrative only.

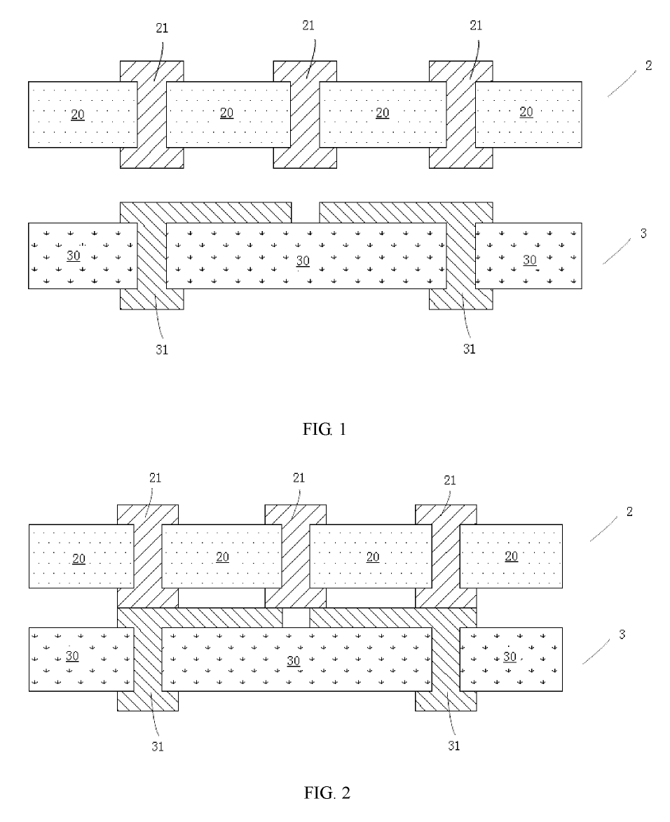

Provide two silicon wafers with completed Through-Silicon-Via structure and interconnection solder joints. FIG. 1 is the schematic view of the structure of the silicon wafers provided. As shown in FIG. 1, in Silicon wafer 2, Number 20 indicates the silicon part, Number 21 indicates the part of the Through-Silicon-Via and the interconnection solder joints, wherein the part between silicon parts 20 is the Through-Silicon-Via part, the part on the front and back faces of the silicon parts 20 (the upper and lower parts in the figure) is the part of interconnection solder joints; in Silicon 3, Number 30 indicates the silicon part, Number 31 indicates the part of the Through-Silicon-Via and the interconnection solder joints, wherein the part between silicon parts 30 is the Through-Silicon-Via part, the part on the front and back faces of the silicon parts 30 (the upper and lower parts in the figure) is the part of interconnection solder joints.

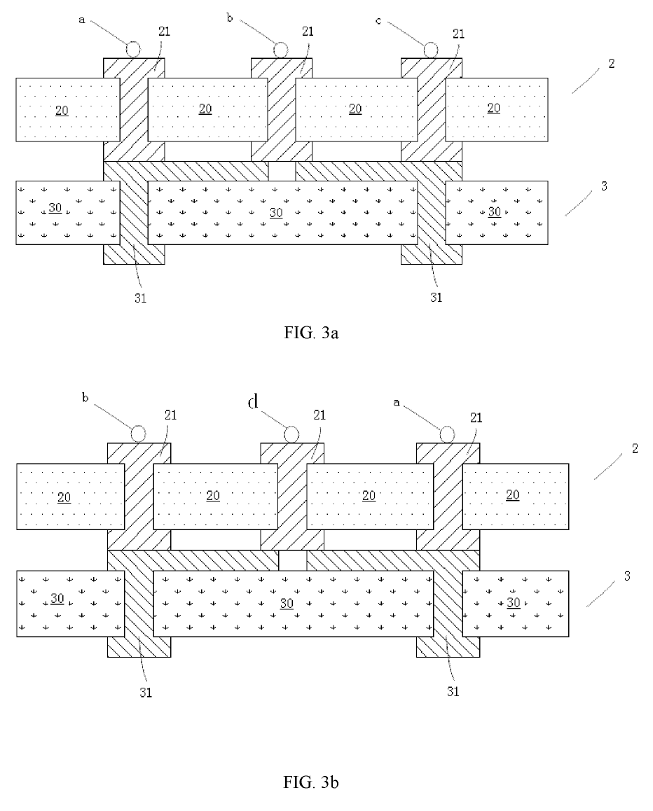

Next, stack and interconnect the silicon wafer 2 and silicon wafer 3, as shown in FIG. 2.

When silicon wafer 2 contacts silicon wafer 3, silicon wafer 2 and silicon wafer 3 may have an alignment deviation, which may influence the interconnection resistance and further affect the performance of the integrated circuit. By the well-known method of Wheatstone bridge for measurement of resistance, silicon wafer 2 and silicon wafer 3 can be aligned and calibrated.

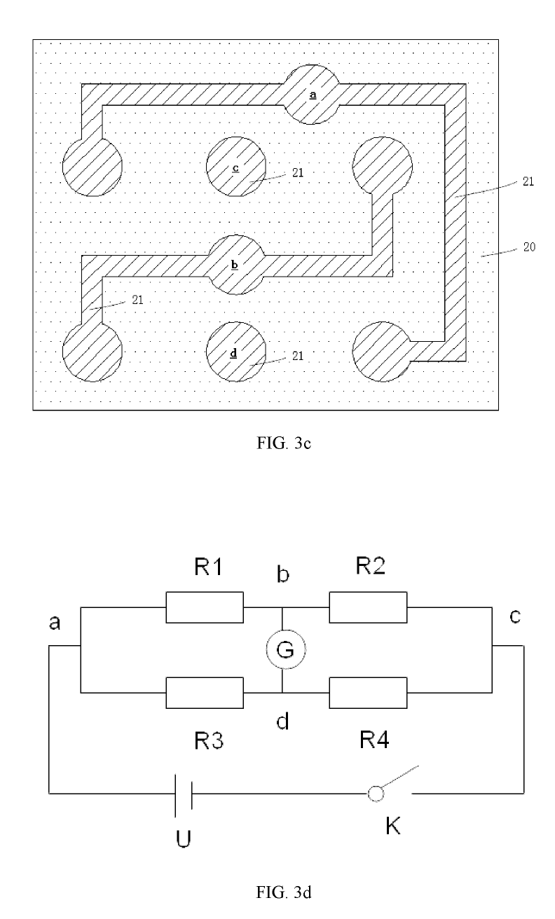

In the structure as shown in FIG. 2, select four measurement nodes of a, b, c and d, then there exists a resistance R1 between node a and b, a resistance R2 between node b and c, a resistance R3 between node a and d, a resistance R4 between node d and c. The layout of the measurement nodes of a, b, c, d is as shown FIG. 3. In combination with FIGS. 3a and 3b, the specific location of each node in the silicon wafers can be understood, wherein FIGS. 3a and 3b show the silicon wafer stacking and interconnection structure seen from two different directions.

Provide a power supply U and a switch K between node a and node c, set a voltage meter G between node b and node d, thus a Wheatstone bridge circuit is formed, wherein the equivalent circuit is as shown in FIG. 3c.

When silicon wafer 2 and silicon wafer 3 are accurately aligned, there will be R1*R4=R2*R3. According to the principle of resistance measurement by means of balanced Wheatstone bridge, node b and node d at this time have the same potential. Therefore, by adjusting the silicon wafer 2 and 3, make the measurement value of voltage meter G show zero, then silicon wafer 2 and silicon wafer 3 can achieve accurate alignment.

As stated above, without deviating from the spirit and scope of the present invention, many other embodiments with big differences may be formed. It should be understood that, except for those defined in the Claims, the present invention is not limited to specific examples in the Specification.

1-5. (canceled)

6. A method of silicon wafer alignment used in through-silicon-via interconnection, the method comprising:
providing two or more silicon wafers with a completed through-silicon-via structure;
forming interconnected microscale solder joints on a front face and a back face of each of the silicon wafers;
stacking and electrically interconnecting the silicon wafers; and
aligning and calibrating the stacked and interconnected silicon wafers.

7. The method of claim 6, wherein the through-silicon-via structure comprises a conductive layer and an insulating layer positioned to separate the conductive layer from the through-silicon-via surface.

8. The method of claim 7, wherein the insulating layer is made of silicon dioxide, silicon nitride or the insulating substance of their combination.

9. The method of claim 7, wherein the insulating layer is formed of silicon dioxide, silicon nitride or a combination thereof.

10. The method of claim 7, wherein the conductive layer comprises aluminum, copper or doped polycrystalline silicon.

11. The method of claim 6, wherein the aligning and calibrating the silicon wafers comprises forming a Wheatstone bridge circuit.

12. The method of claim 6, wherein the aligning and calibrating the silicon wafers comprises:
positioning an upper silicon wafer and a lower silicon wafer such that the solder joints on the back face of the upper silicon wafer contact the solder joints on the front face of the lower silicon wafer and form a plurality of nodes;
connecting the plurality of nodes into pairs of nodes to form a plurality of resistance groups, wherein the pair of nodes comprising each resistance group are connected in series;
connecting the plurality of resistance groups in parallel;
applying a voltage across the plurality of resistance groups in parallel;
comparing the voltage across the plurality of resistance groups to get a voltage difference; and
adjusting the position of the wafers as necessary to minimize the voltage difference.

13. A method of silicon wafer alignment used in through-silicon-via interconnection, the method comprising:
providing two or more silicon wafers with a completed through-silicon-via structure;
forming interconnected microscale solder joints on a front face and a back face of each of the silicon wafers;
stacking the silicon wafers;
aligning the stacked silicon wafers.

14. The method of claim 13, further comprising electrically interconnecting the stacked silicon wafers.

15. The method of claim 14, further comprising electrically calibrating the stacked silicon wafers.
